(19) United States
(12) Patent Application Publication
(10) Pub. No.: US 2014/0370643 A1
(43) Pub. Date: Dec. 18, 2014

(54) FORMULATION FOR ACIDIC WET CHEMICAL ETCHING OF SILICON WAFERS

(71) Applicants: Eric Stern, Cambridge, MA (US); Bradley M. West, New Milford, CT (US); Jason Criscione, Billerica, MA (US)

(72) Inventors: Eric Stern, Cambridge, MA (US); Bradley M. West, New Milford, CT (US); Jason Criscione, Billerica, MA (US)

(73) Assignee: 1366 TECHNOLOGIES INC, Lexington, MA (US)

(21) Appl. No.: 14/240,075

(22) PCT Filed: Aug. 22, 2012
(86) PCT No.: PCT/US12/51939

§ 371 Date: Sep. 3, 2014

Related U.S. Application Data
(60) Provisional application No. 61/526,076, filed on Aug. 22, 2011.

(51) Int. Cl. H01L 31/0236; C09K 13/08

(52) U.S. Cl. CPC H01L 31/02366; C09K 13/08
USPC 438/71; 252/79.3

(57) ABSTRACT

Acid etch compositions for etching multicrystalline silicon substrates are disclosed which may include hydrofluoric acid, an oxidizer, an acid diluent, and soluble silicon. The soluble silicon may be hexafluorosilicic acid or ammonium fluorosilicate. Silicon substrates patterned with organic resist may be used with the acid etch compositions for selective silicon patterning for solar cell applications.

### CROSS-REFERENCE TO RELATED APPLICATION

This application claims priority from U.S. Provisional Application Ser. No. 61/526,076, filed Aug. 22, 2011, which is incorporated herein by reference.

### BACKGROUND

This disclosure relates to acid wet etching of silicon wafers.

In order to maximize silicon solar cell efficiencies the silicon surface is often textured to reduce reflectivity and, in turn, enhance photon capture. This front (“sunny”) side texture may be at a sub-millimeter, micro- or nano-scale. Texturing is most commonly achieved by etching a silicon wafer, which may be a monocrystalline or multicrystalline wafer, with wet chemical etchants in batch or in-line processes. Monocrystalline silicon wafers may be etched with alkaline etchants that take advantage of their crystalline structure to yield pyramids that are well suited for limiting reflectivity. Multicrystalline wafers have no such crystalline structure to exploit and, in turn, are commonly etched with acidic etchants.

Acid etching may be achieved with an acidic mixture containing hydrofluoric acid (HF) and a silicon oxidizer, such as nitric acid (HNO₃), as known to those skilled in the art. Prior work may use saw-damaged or smooth mutlticrystalline silicon wafers (depending on the wafer production process). However, these methods may not be suited to etching patterned substrates and do not provide a consistent etching composition over the course of many wafers, as detailed below.

### SUMMARY

Formulations useful for acidic wet chemical etching of silicon wafers are described. The formulations are used in processing of silicon to provide silicon surfaces having reduced reflectivity and enhanced photon capture. In one aspect, soluble silicon additives are included in the as-prepared formulations.

In one aspect, a method of patterning silicon, includes exposing a silicon substrate patterned with organic resist on at least one surface to an as-prepared etching composition, the etching composition comprising hydrofluoric acid, at least one oxidizer capable of oxidizing silicon, and soluble silicon, wherein the etching composition etches exposed silicon surface of the silicon substrate without removing the organic resist.

In one or more embodiments, the method further includes per unit silicon etched, removing a volume fraction of the etching composition while simultaneously replenishing the etchant bath with a replenishment solution comprising hydrofluoric acid and at least one aqueous-soluble oxidizer capable of oxidizing silicon.

In one or more embodiments, the soluble silicon is selected from a group consisting of fluorosilicates, silicic acid, silicates, soluble silicon, and combinations thereof.

In one or more embodiments, the fluorosilicate is selected from a group consisting of hexafluorosilicic acid and ammonium fluorosilicate and combinations thereof.

In one or more embodiments, the oxidizer is selected from the group consisting of such as nitric acid, nitrous acid, iodic acid, peroxides, chlorates, perchlorates, chromates, dichromates, nitrites, nitrates, permanganates, persulfates, iodates, periodates and combinations thereof.

In any of the preceding embodiments, the method includes one or more diluents.

In any of the preceding embodiments, the method includes one or more acid diluents.

In one or more embodiments, the acidic diluents are selected from the group consisting of acetic, glacial acetic, phosphoric, sulfuric, sulfurous, pyrophosphoric, phosphorus, chromic, chloric, trifluoromethanesulfonic, methanesulfonic, trifluoroacetic, trichloroacetic, formic, and/or citric acids; poly(4-styrenesulfonic acid), poly(vinylsulfonic acid), poly(styrene-alt-maleic acid), poly(acrylic acid), poly(methacrylic acid), and combinations thereof.

In one or more embodiments, the replenishment solution further contains a diluent.

In one or more embodiments, the diluents are selected from the group consisting of polymers, surfactants, and/or polymer acids, such as poly(ethylene glycol), poly(4-styrenesulfonic acid), poly(vinylsulfonic acid), poly(styrene-alt-maleic acid), poly(acrylic acid), poly(methacrylic acid), and/or fluorocarbon surfactants that include an aliphatic fluorocarbon group (e.g., ZONYL® FSA and FSN fluorosurfactants, E.I. Du Pont de Nemours and Co., Wilmington, Del.), fluorinated alkyl alkoxylates (e.g., FLUORAD® surfactants, Minnesota Mining and Manufacturing Co., St. Paul, Minn.), hydrocarbon surfactants that have an aliphatic group (e.g., alkylphenol ethoxylates comprising an alkyl group having about 6 to about 12 carbon atoms, such as octylphenol ethoxylate, available as TRITON® X-100, Union Carbide, Danbury, Conn.), polyoxyethylene sorbitan monolaurate or monooleate (e.g., TWEEN® 20 and TWEEN® 80, available from ICI Americas, Inc.), a triblock copolymer of ethylene oxide and propylene oxide (e.g., PLURONIC® P104 and PLURONIC® F127, available from BASF

Corp., Mount Olive, N.J.), silicone surfactants such as silanes and siloxanes (e.g., polyoxyethylene-modified polydimethylsiloxanes such as DOW CORNING® Q2-5211 and Q2-5212, Dow Corning Corp., Midland, Mich.), fluorinated silicone surfactants (e.g., fluorinated polysilanes such as LEVELENE® 100, Ecology Chemical Co., Watertown Mass.), and combinations thereof.

In one or more embodiments, the as-prepared etching composition includes 1.4 to 7.1 M of hydrofluoric acid; 0.01 to 7.75 M of at least one oxidizer capable of oxidizing silicon; and 0.15 to 2.2 M of soluble silicon.

In one or more embodiments, the as-prepared etching composition includes 2.5 to 7.1 M of hydrofluoric acid; 1 to 7.75 M of at least one oxidizer capable of oxidizing silicon; and 0.3 to 1.9 M of soluble silicon.

In one or more embodiments, the as-prepared etching composition includes 2.5 to 5.8 M of hydrofluoric acid; 3.8 to 7.75 M of at least one oxidizer capable of oxidizing silicon; and 0.6 to 1.7 M of soluble silicon.

In one or more embodiments, the as-prepared etching composition further includes 1.1 to 7.5 M of one or more acid diluents.

In one or more embodiments, the as-prepared etching composition further includes 1.3 to 5.4 M of one or more acid diluents.

In one or more embodiments, the as-prepared etching composition further includes 1.7 to 4.6 M of one or more acid diluents.

In one or more embodiments, the resulting patterned silicon substrate has lower average reflectance than the same silicon substrate etched with the as-prepared etching composition wherein water is substituted for the soluble silicon.

In another aspect, an as-prepared aqueous acid etching composition includes: 1.4 to 7.1 M of hydrofluoric acid; 0.01 to 7.75 M of at least one oxidizer capable of oxidizing silicon; and 0.15 to 2.2 M of soluble silicon.

In one or more embodiments, the as-prepared aqueous acid etching composition includes 2.5 to 7.1 M of hydrofluoric acid; 1 to 7.75 M of at least one oxidizer capable of oxidizing silicon; and 0.3 to 1.9 M of soluble silicon.

In one or more embodiments, the as-prepared aqueous acid etching composition includes 2.5 to 5.8 M of hydrofluoric acid; 3.8 to 7.75 M of at least one oxidizer capable of oxidizing silicon; and 0.6 to 1.7 M of soluble silicon.

In one or more embodiments, the soluble silicon is selected from a group consisting of fluorosilicates, silicic acid, silicates and soluble silicon.

In one or more embodiments, the fluorosilicate is selected from a group consisting of hexafluorosilicic acid and ammonium fluorosilicate.

In one or more embodiments, the as-prepared aqueous acid etching composition further including one or more acid diluents.

In one or more embodiments, the one or more acid diluent is present at a concentration of 1.1 to 7.5 M.

In one or more embodiments, the one or more acid diluent is present at a concentration of 1.3 to 5.4 M.

In one or more embodiments, the one or more acid diluent is present at a concentration of 1.7 to 4.6 M.

In one or more embodiments, the acidic diluents are selected from the group consisting of acetic, glacial acetic, phosphoric, sulfuric, sulfurous, pyrophosphoric, phosphorus, chromic, chloric, trifluoromethanesulfonic, methanesulfonic, trifluoroacetic, trichloroacetic, formic, and/or citric acids; poly(4-styrenesulfonic acid), poly(vinylsulfonic acid), poly(styrene-alt-maleic acid), poly(acrylic acid), poly(methacrylic acid) and combinations thereof.

In one or more embodiments, the oxidizer is selected from the group consisting of nitric acid, nitrous acid, iodic acid, peroxides, chlorates, perchlorates, chromates, dichromates, nitrites, nitrates, permanganates, persulfates, iodates, periodates and combinations thereof.

In yet another aspect, a method of etching a silicon surface, includes providing an as-prepared aqueous acid etching composition comprising 1.4 to 7.1 M aqueous hydrofluoric acid, 0.01 to 7.75 M of at least one aqueous oxidizer capable of oxidizing silicon, and 0.15 to 2.2 M aqueous hexafluorosilicic acid; and exposing a silicon substrate to the as-prepared etching composition.

### BRIEF DESCRIPTION OF THE DRAWINGS

The features and advantages of certain embodiments are illustrated in the accompanying drawings, which are presented for the purpose of illustration only and are not intended to be limiting of the invention.

FIG. 1A is a schematic illustration of a substrate wafer (such as silicon) covered with patterned resist material for use in the etching method according to one or more embodiments.

FIG. 1B is a schematic illustration of an etched substrate wafer according to one or more embodiments

FIG. 2 is an electron micrograph of an exemplary silicon substrate covered with patterned resist material for use in the etching method according to one or more embodiments.

FIG. 3A is a schematic of acid concentration vs bath lifetime illustrating the change of concentration over time, particularly at the onset of etching for a conventional acid etching composition; the bath lifetime is divided into three regions: a “new” bath at the initial timepoint, e.g. prior to the etching of any wafers; a “stabilization” period during which time the reactant and product concentrations stabilize; and a “continuous” period during which time the react and product concentrations are stable within an acceptable window.

FIG. 3B is a schematic of acid concentration vs bath lifetime illustrating the change of concentration over time, particularly at the onset of etching, according to one or more embodiments of the present disclosure; the bath lifetime is divided into three regions: a “new” bath at the initial timepoint, e.g. prior to the etching of any wafers; a “stabilization” period during which time the product concentration(s) stabilize; and a “continuous” period during which time the react and product concentrations are stable within an acceptable window.

FIG. 4 is an optical micrograph of a patterned silicon wafer after etching with a composition that contains no water or soluble silicon additive and subsequent mask removal according to one or more embodiments.

FIG. 5 is an optical micrograph of a pattered silicon wafer after etching with a composition including a water diluent in place of a soluble silicon additive and subsequent mask removal according to one or more embodiments.

FIG. 6 is an optical micrograph of a pattered silicon wafer after etching with a composition including a soluble silicon additive and subsequent mask removal according to one or more embodiments.

FIG. 7 is a plot of reflectivity vs. wavelength for two samples of pattered silicon etched with compositions including either a soluble silicon additive or a water diluent in place of a soluble silicon additive respectively according to one or more embodiments.

FIG. 8 is a plot of the concentrations of HF, HNO₃, H₂SO₄, and H₂SiF₆ versus total grams of Si removed according to one or more embodiments of the current disclosure. This shows stable acid concentrations, defined as remaining within ±10%, beginning with the first wafer etched.

### DETAILED DESCRIPTION

Texturing methods and texturing etch compositions are described. The acid etch compositions are used in conjunction with silicon wafers patterned with resist to provide silicon surfaces having reduced reflectivity and increased photon absorption.

In one aspect of the present disclosure, silicon wafers patterned with resist are etched in an as-prepared etching composition including hydrofluoric acid, at least one oxidizer, and at least one soluble silicon additive. The etching process provides advantages over prior art silicon texturing methods by decreasing costs, providing a more consistent etching composition over the course of etching many wafers, and providing consistent etch results. In addition, the resultant wafers demonstrate improved absorption (or reduced reflectance) of incident light. “As-prepared” etching composition refers to a composition, e.g., chemical components and their relative concentrations, as the etching solution is made and before any etching occurs. The initial concentrations of the components in the “as-prepared” etching composition are defined as their concentrations before any Si etching occurs. As is discussed in further detail below, the composition of the etching composition changes over time as silicon wafers are etched, so that the composition of the as-prepared composition is distinguishable from the composition of the etching bath during later stages of use.

In some embodiments, it has been found that the above-noted and other benefits can be observed with an as-prepared etching composition including 1.4 to 7.1 M of hydrofluoric acid, 0.01 to 7.75 M of at least one oxidizer capable of oxidizing silicon (such as nitric acid, nitrous acid, iodic acid, peroxides, chlorates, perchlorates, chromates, dichromates, nitrites, nitrates, permanganates, persulfates, iodates, periodates, etc.), and 0.15 to 2.2 M of soluble silicon (such as hexafluorosilicic acid and/or ammonium fluorosilicate). In other embodiments, the etching composition includes 2.5 to 7.1 M of hydrofluoric acid, 1 to 7.75 M of at least one oxidizer capable of oxidizing silicon, and 0.3 to 1.9 M of soluble silicon. In yet other embodiments, the etching composition includes 2.5 to 5.8 M of hydrofluoric acid, 3.8 to 7.75 M of at least one oxidizer capable of oxidizing silicon, and 0.6 to 1.7 M of soluble silicon. All listed molarities in this disclosure refer to the final molarity in the combined composition or bath. As used herein “soluble silicon” refers to silicon in a form that is water soluble, such as silicic acid, silicates, fluorosilicates, hydrated silicas and the like that have solubility in the etching bath. The etching bath may include one or more type of soluble silicon. In one or more embodiments, the soluble silicon is a reaction by-product from the silicon etch process.

The etching compositions may also include diluent acids. Diluent acids are acids that do not directly participate in the silicon etching process, such as acetic acid, phosphoric acid, and sulfuric acid, and the like. One or more diluent acids can be included at 1.1 to 7.5 M. In some embodiments one or more diluent acids can be included at 1.3 to 5.4 M. In some embodiments one or more diluent acids can be included at 1.7 to 4.6 M. Water is optionally added to obtain desired concentrations of constituent components of the etching composition.

In addition to water present in the concentrated acid solutions, water may be specifically added to dilute the HF and HNO₃ concentrations in the texture etch. This dilution may be performed to achieve at least one of the following: 1) slower etch times; 2) more controlled etching reactions; 3) lower volumes of required HF and HNO₃ makeup required per Si wafer etched (e.g. per unit mass of Si solubilized) to achieve constant acid concentrations; etc. Other diluents may be used in place of or in addition to added water: acids, such as acetic, glacial acetic, phosphoric, sulfuric, sulfurous, pyrophosphoric, phosphorus, chromic, chloric, trifluoromethanesulfonic, methanesulfonic, trifluoroacetic, trichloroacetic, formic, citric acids; intermediates and/or potential intermediates, such as nitrites, nitrous acid, fluoride salts, and/or bifluorides; polymers, surfactants, and/or polymer acids, such as poly(ethylene glycol), poly(4-styrenesulfonic acid), poly(vinylsulfonic acid), poly(styrene-alt-maleic acid), poly(acrylic acid), poly(methacrylic acid), and/or fluorocarbon surfactants that include an aliphatic fluorocarbon group (e.g., ZONYL® FSA and FSN fluorosurfactants, E.I. Du Pont de Nemours and Co., Wilmington, Del.), fluorinated alkyl alkoxylates (e.g., FLUORAD® surfactants, Minnesota Mining and Manufacturing Co., St. Paul, Minn.), hydrocarbon surfactants that have an aliphatic group (e.g., alkylphenol ethoxylates comprising an alkyl group having about 6 to about 12 carbon atoms, such as octylphenol ethoxylate, available as TRITON® X-100, Union Carbide, Danbury, Conn.), polyoxyethylene sorbitan monolaurate or monooleate (e.g., TWEEN® 20 and TWEEN® 80, available from ICI Americas, Inc.), a triblock copolymer of ethylene oxide and propylene oxide (e.g., PLURONIC® P104 and PLURONIC® F127, available from BASF Corp., Mount Olive, N.J.), silicone surfactants such as silanes and siloxanes (e.g., polyoxyethylene-modified polydimethylsiloxanes such as DOW CORNING® Q2-5211 and Q2-5212, Dow Corning Corp., Midland, Mich.), fluorinated silicone surfactants (e.g., fluorinated polysilanes such as LEVELENE® 100, Ecology Chemical Co., Watertown Mass.), and combinations thereof. As with added water, such diluents may be included to achieve at least one of the following: 1) slower etch times; 2) more controlled etching reactions; 3) improved light capturing ability of the resulting Si surface; 4) improved resist stability.

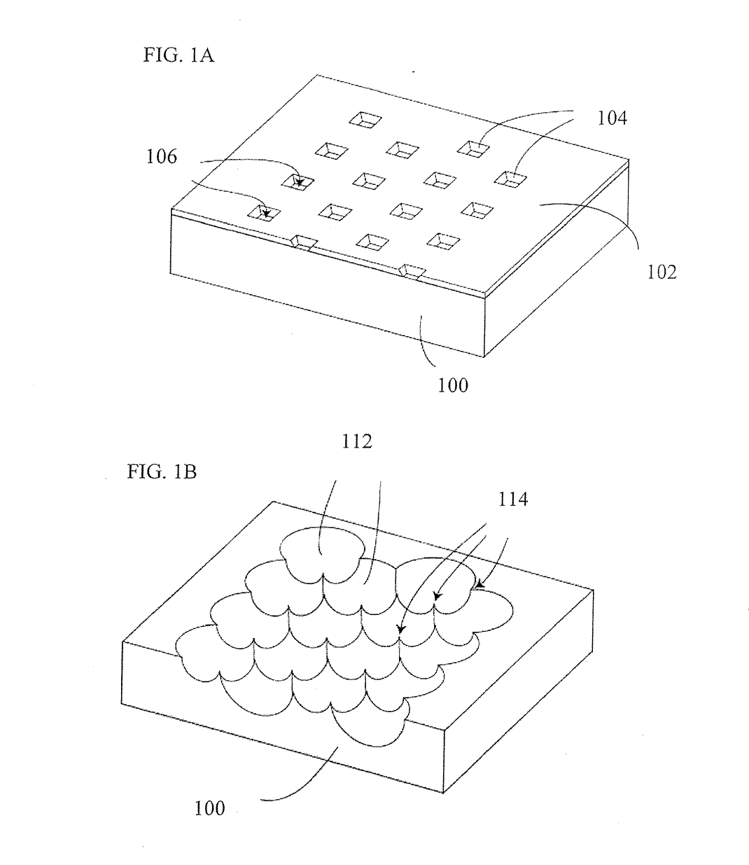

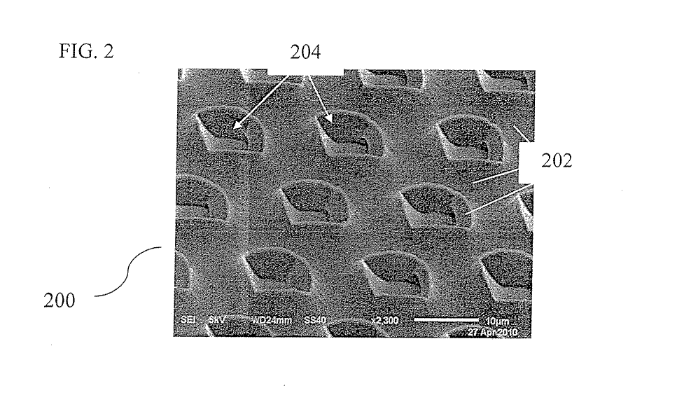

In some embodiments of this disclosure, silicon substrates are textured by utilizing an organic mask. For example, an organic resist can be used to define a pattern on the silicon surface to selectively expose portions of the silicon surface to the silicon etching bath. Many resist patterns are suitable for this purpose. For example, the resist may be patterned such that it provides periodic circular, square, rectangular or other shapes that form a periodic or regular surface pattern, such as a hexagonal closest-packed “honeycomb” array, on the silicon wafer. This mask may be comprised of at least one organic material that is resistant or somewhat resistant to etching or decomposition under the etching conditions of the bath. FIG. 1A shows schematically a substrate wafer 100 (such as silicon) covered with patterned resist material 102, leaving regions 104 of the substrate exposed under holes 106, from where the resist has been removed. The substrate is further subjected to some shaping process, typically an etching process. Exposed portions 104 of the substrate 100 are removed by an action, such as etching, and portions of the substrate that are protected by the resist remain. The resulting surface may be hemispherical pits, as shown in FIG. 1B, defined by etched away regions 112 and un-etched, or less-etched regions 114. An exemplary masked silicon wafer structure is shown in FIG. 2. The silicon substrate 200 is covered with resist (mask material) 202 which contains an array of holes 204 through which the underlying Si is exposed. The resist layer can be patterned using a variety of methods to provide a range of patterns. Suitable methods include soft lithographic techniques and nanoimprint lithography. Soft lithography involves use of an elastomeric stamp with raised features to define a pattern at the micro- or nano-scale. Further details on resist layer patterning and deposition can be found in Provisional Applications No. PCT/US2008/002058 (filed on Feb. 15, 2008), US PCT/US2009/02423 (filed on Apr. 17, 2009), U.S. 61/538,489 (filed on Sep. 23, 2011), U.S. 61/538,542 (filed on Sep. 23, 2011), and U.S. 61/546,384 (filed on Oct. 12, 2011).

During etching, at least the masked silicon surface is exposed to the acid etching solution so that the exposed areas are selectively etched. The etching composition according to one or more embodiments includes an etchant solution containing HF, at least one oxidizer capable of oxidizing silicon directly or indirectly, at least one water soluble silicon compound and other added diluents, such as water and acid. The texture resulting from etching a resist-patterned sample consists of a honeycomb array of hemispherical pits with such a composition in the silicon, such as that illustrated schematically in FIG. 1B. In some embodiments, a single, large “etch bath” may be used to texture etch multiple wafers. This may take the form of a “batch” etch process, where multiple wafers are loaded into a carrier before being placed in the etchant solution, or an “inline” etch process, where wafers traverse laterally (e.g., horizontally) through the etchant solution.

General acidic mixtures involving HF and a silicon oxidizer etch silicon surfaces (e.g., remove surface silicon), by first oxidizing and subsequently dissolving Si atoms into the solution. These steps are commonly achieved with an oxidizer, such as HNO₃, and HF, respectively. During this reaction, HF and HNO₃ are consumed. Although HNO₃ is considered to be the source of the silicon oxidation, studies have shown that silicon may not be directly oxidized by HNO₃ itself but by a nitrous oxide (NOₓ) compound that is auto-catalytically generated during the reaction. One of the byproducts of the etch reaction may take the form of hexafluorosilicic acid, ammonium hexafluorosilicate, or other soluble silicon. Another significant etch product is water (H₂O). Thus, over time, HNO₃ and HF concentrations decline, while the level of soluble silicon (e.g. H₂SiF₆) and water increase. The overall reaction is generally accepted to be:

3Si+4HNO₃+18HF→3H₂SiF₆+4NO+8H₂O [Rxn. 1]

In order to keep etch acid concentrations stable over time as multiple wafers are etched in the bath, a “feed/bleed” system may be used. Such a system removes a determined volume fraction of the etch composition per wafer etched or per unit time (“bleed”). A similar volume of “fresh,” concentrated acid (e.g., HF and HNO₃) is added to the bath (“feed”). The volume fractions removed and added, as well as the composition of the added “feed” or “makeup” may be determined through a combination of theoretical and practical considerations. Theoretical considerations are based on the stoichiometries given in Rxn. 1 and the mols of silicon removed per wafer. Practical considerations include the evaporation of HF, the loss of the oxidizer, such as HNO₃, due to the presence of iron and other impurities, and the loss of Si as SiF₄, and others.

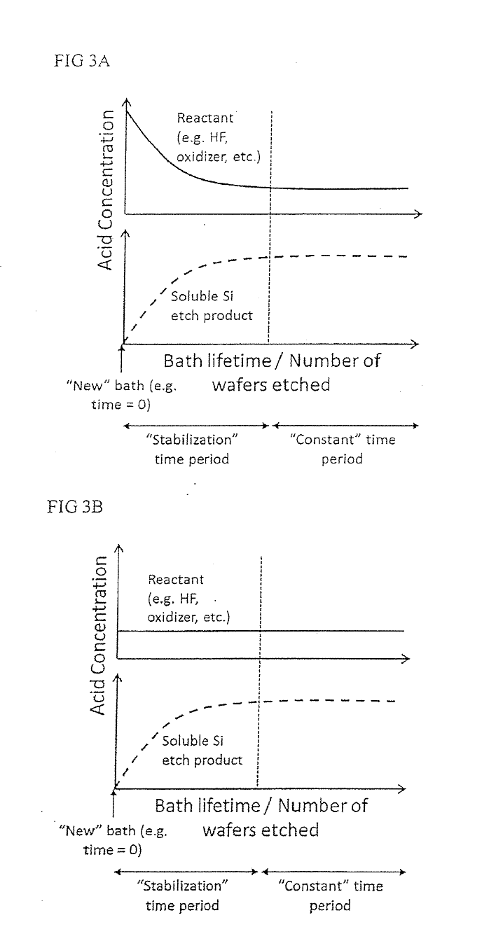

For prior art etching compositions (e.g., ones that do not include soluble silicon in the “as-prepared” composition), this bath may contain HF and oxidizer (e.g., HNO₃) in addition to water present in the concentrated acid solutions. Commercially available concentrated HF and HNO₃ are available as aqueous solutions thus water is present in all texture etch baths. The concentrations of all components of a batch or inline etch bath equipped with a feed/bleed system changes over the course of etching multiple wafers, e.g. over the bath lifetime, as shown schematically in FIG. 3A. For example, as noted in the upper curve the reactants involved in the etching process such as HF and HNO₃ decrease in concentration until a stable composition is reached. The stable concentration reached, as well as the rate with which it is achieved, is a function of multiple parameters, including the quantity of Si etched per wafer, the bath volume, the HF and oxidizer concentrations, etc. Similarly, the soluble silicon etch product (e.g., H₂SiF₆), increases in concentration from zero or near-zero before the first wafer is etched. If the feed/bleed is tuned such that HF and oxidizer concentrations eventually reach a suitably constant level—defined in FIG. 3A as the “constant” regime,—the soluble silicon concentration eventually stabilizes over the course of etching many wafers. Thus, etching processes using as-prepared acid etch compositions containing HF and HNO₃ includes a period of variable composition during the “stabilization” time period. Due to this variable concentration of etching acids during the stabilization period, the silicon wafer will experience different etching conditions and demonstrate variable etching effects on a wafer-to-wafer basis until the bath is stabilized.

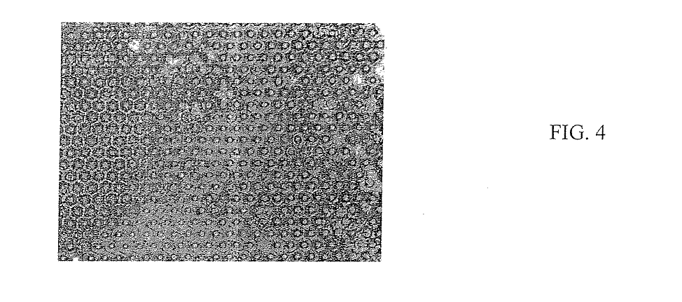

In certain embodiments, etching a silicon substrate coated with patterned resist during a representative timepoint during the “stabilization” period shown in FIG. 3A is detrimental to the formation of the pattern illustrated in FIG. 1B. A representative micrograph is given in FIG. 4. In some embodiments, large variations in etching are observed across the wafer due to the inability of the organic resist to withstand high HF and HNO₃ concentrations. See, e.g., Comparative Example 1.

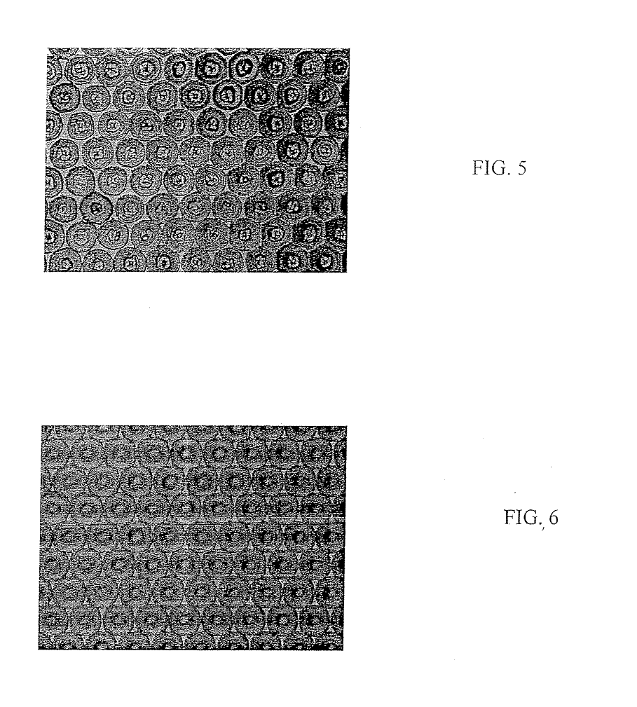

Previous attempts to achieve more constant reactants during the “stabilization” period included using additional water as a diluent. In this way, the HF and oxidizer (e.g. HNO₃) concentrations are set at their “constant” region concentrations (as defined in FIG. 3A) in the “new” bath. Thus, these concentrations remain suitably constant throughout the bath lifetime, provided a properly tuned feed/bleed is used, as illustrated in FIG. 3B. Although the added water may serve as an effective diluent for maintaining suitably constant acid concentrations, this excess water in typical acid etch compositions (without a soluble silicon additive) has been empirically observed to be detrimental to the optical properties of the wafers patterned by the organic mask method described herein. The etching performance of the HNO₃—HF system is dependent on the ratio of these acids as well as the water content. Increasing water content for a given acid ratio roughens the texture of the resulting silicon surface, as shown in FIG. 5. This is specifically detrimental to the masked etching of the individual pits that comprise the honeycomb pattern because it limits the achievable pit depths. Furthermore, the side walls of the pits can be roughened, resulting in greater reflection and reduced light capture within the silicon device, as shown in FIG. 6 (solid line). See, e.g., Example 2 and Comparative Example 2.

In one embodiment of the disclosure, the problems of the previous etching baths are addressed by incorporating soluble silicon as a component in an as-prepared etching composition or bath. The soluble silicon can be added instead of water, thereby reducing the water content of the bath and mitigating the resulting deleterious effects of water. Exemplary soluble silicons include hexafluorosilicic acid (H₂SiF₆) and ammonium hexafluorosilicate [(NH₄)₂SiF₆]. By adding a byproduct of the etch bath and displacing the water diluent, the initial addition of the soluble Si etch product (e.g., H₂SiF₆), the composition of the bath is controlled without changing the chemistry of the bath. Furthermore, because the reaction product of the etching process is soluble silicon (i.e., H₂SiF₆), unlike all other acid diluents, the soluble silicon (i.e., H₂SiF₆) is replenished by the etch reaction and need not be replenished during the feed/bleed process.

Addition of a soluble silicon in the as-prepared etching composition may confer one or more of the following benefits to the aforementioned etching methods: 1) improvement in light capturing performance of the textured Si surface; 2) decrease in the volume of concentrated acid feed/bleed required per Si wafer etched, e.g. per unit mass of Si removed; 3) decrease in the required concentration(s) of at least one of HF, oxidizer (i.e., HNO₃), added diluents in the texture etch; 4) improvement in the etch consistency, such that all wafers etched throughout the lifetime of a bath are similarly textured; and 5) extension of the lifetime, e.g. the number of wafers that are etched, of a single bath; etc.

The acid “feed system” solution (e.g., the replenishing solution added continuously to the bath) need not include soluble silicon because this is generated by the Si etch reaction and, in turn, is auto-replenished by the etching process itself. Through proper calculation of the feed/bleed volumes and concentrations, this may enable soluble silicon to be maintained at a suitably constant level during the entire lifetime of a texture etching bath. Water, an additional product of the etching reaction, can also be replenished in this way. Through analysis of the constituents of the texture etch bath during the course of etching multiple wafers similarly in a given system, e.g. etching tool and controlled environment, values for the feed/bleed volumes and concentrations may be set to maintain starting acid concentrations within a suitable range throughout the lifetime of the bath.

Referring back to FIG. 3, this would mean that the “stabilization” time period (the time period where the concentration of components is changing) which was observed in prior art baths can eliminated using this novel etching method, and the concentration of all reactants and by-products would begin as flat, horizontal lines from time “0”. With this novel feature, wafers exposed to the acid etching composition at any point in the “lifetime” of the bath will experience identical etching conditions and variability in etching performance is reduced.

### Example 1

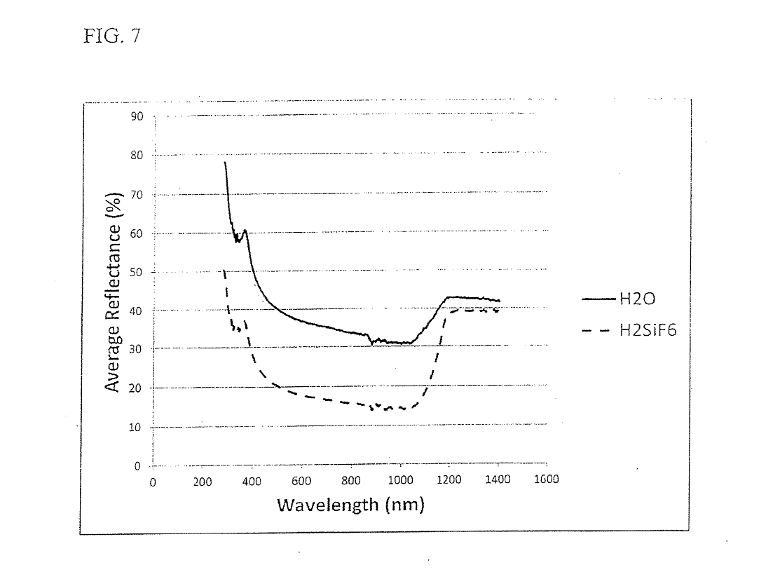

A representative Si surface was patterned with organic resist similarly to the sample in FIG. 2 and etched using a solution comprised of 2.84 M HF, 4.80 M HNO₃, 2.70 M H₂SO₄, and 1.39 M H₂SiF₆. The resultant etched surface is shown in FIG. 4 after organic resist (i.e. mask) removal. The sidewalls of the Si pits were smooth, resulting in improved light capturing ability of the surface relative to the sample described in Comparative Example 2, FIG. 7.

### Comparative Example 1

A representative Si surface was patterned with organic resist similarly to the sample in FIG. 2. The sample was then etched using a solution comprised of 5.97 M HF, 9.91 M HNO₃, and 2.70 M H₂SO₄. The resultant etched surface is shown in FIG. 4 after organic resist (i.e. mask) removal. The significant variations in pit definition and etch quality, as well as the roughness of the etched surfaces, were due to the high HF and HNO₃ concentrations relative to those in Example 1 and Comparative Example 2.

### Comparative Example 2

An exemplary silicon surface was patterned with organic resist similarly to the sample in FIG. 2. The patterned wafer was exposed to an etchant composition containing 2.84 M HF, 4.80 M HNO₃, and 2.70 M H₂SO₄. The resulting structure consisted of a honeycomb array of pits in the Si substrate of uniform appearance, in contrast to Comparative Example 1 and owing to the lower HF and HNO₃ concentrations. A representative micrograph after mask removal is shown in FIG. 5. Although the pits are well-defined, the micrograph shows that etched surfaces within most pits are rough (e.g. not smooth).

The plot of reflectivity vs. wavelength for the two samples from Example 1 and Comparative Example 2 are shown in FIG. 6. The plot shows a marked improvement in the light capturing ability of the surface as etched with a soluble silicon additive as in Example 1 (as shown by the dashed line) as opposed to the surface etched in a composition with a water diluent as in Comparative Example 2 (as shown by the solid line).

### Example 2

A 20 L in-line etch bath was filled with an etchant comprised of 2.31 M HF, 5.19 M HNO₃, 2.70 M H₂SO₄, and 1.38 M H₂SiF₆. A makeup solution (the “feed” solution) was comprised of 13.35 M HF, 6.38 M HNO₃, and 2.40 M H₂SO₄. During continual etching of silicon wafers patterned similarly to the sample in FIG. 2, 29.8 mL of makeup was added (and a similar volume fraction of etchant, “bleed” was removed) per gram of silicon etched.

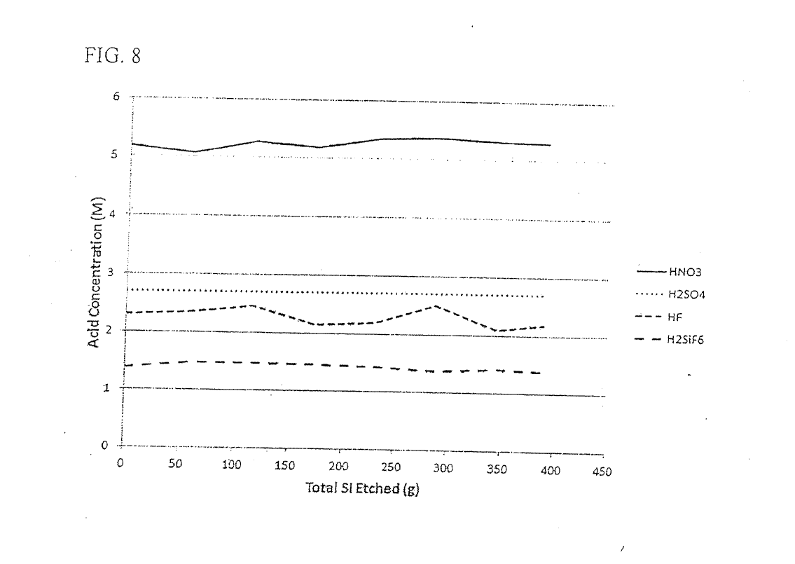

The stable levels of HF, HNO₃, H₂SO₄, and H₂SiF₆ concentrations over the course of etching are depicted in FIG. 8. Note that these levels remained within ±10% of the original concentrations. Exclusively in the case of H₂SiF₆, the initial concentration was maintained although the replenishment solution does not contain H₂SiF₆ because H₂SiF₆ is a soluble silicon etch product of the silicon etching reaction, Rxn. 1.

The foregoing discussion should be understood as illustrative and should not be considered to be limiting in any sense. While the inventions have been particularly shown and described with references to preferred embodiments thereof, it will be understood by those skilled in the art that various changes in form and details may be made therein without departing from the spirit and scope of the inventions as defined by the claims.

The corresponding structures, materials, acts and equivalents of all means or step plus function elements in the claims below are intended to include any structure, material, or acts for performing the functions in combination with other claimed elements as specifically claimed.

1. A method of patterning silicon, comprising:
exposing a silicon substrate patterned with organic resist on at least one surface to an as-prepared etching composition, the etching composition comprising hydrofluoric acid, at least one oxidizer capable of oxidizing silicon, and soluble silicon,
wherein the etching composition etches exposed silicon surface of the silicon substrate without removing the organic resist.

2. The method of claim 1 further comprising:
per unit silicon etched, removing a volume fraction of the etching composition while simultaneously replenishing the etchant bath with a replenishment solution comprising hydrofluoric acid and at least one aqueous-soluble oxidizer capable of oxidizing silicon.

3. The method of claim 1, wherein the soluble silicon is selected from the group consisting of fluorosilicates, silicic acid, silicates, soluble silicon, and combinations thereof.

4. The method of claim 3 wherein the fluorosilicate is selected from the group consisting of hexafluorosilicic acid and ammonium fluorosilicate and combinations thereof.

5. The method of claim 1, wherein the oxidizer is selected from the group consisting of nitric acid, nitrous acid, iodic acid, peroxides, chlorates, perchlorates, chromates, dichromates, nitrites, nitrates, permanganates, persulfates, iodates, periodates and combinations thereof.

6. The method of claim 1, wherein the etching composition further comprises at least one diluent.

7. The method of claim 6, wherein said diluent is an acidic diluent.

8. The method of claim 7 wherein the acidic diluent is selected from the group consisting of acetic, glacial acetic, phosphoric, sulfuric, sulfurous, pyrophosphoric, phosphorus, chromic, chloric, trifluoromethanesulfonic, methanesulfonic, trifluoroacetic, trichloroacetic, formic, and citric acids; poly(4-styrenesulfonic acid), poly(vinylsulfonic acid), poly(styrene-alt-maleic acid), poly(acrylic acid), poly(methacrylic acid), and combinations thereof.

9. The method of claim 6, wherein the replenishment solution further contains a diluent.

10. The method of claim 6 wherein the diluent is selected from the group consisting of polymers, surfactants, polymer acids, fluorocarbon surfactants that include an aliphatic fluorocarbon group, fluorinated alkyl alkoxylates hydrocarbon surfactants that have an aliphatic group, polyoxyethylene sorbitan monolaurate or monooleate, a triblock copolymer of ethylene oxide and propylene oxide, silicone surfactants, fluorinated silicone surfactants, and combinations thereof.

11. The method of claim 1, wherein the as-prepared etching composition comprises:
1.4 to 7.1 M of hydrofluoric acid;
0.01 to 7.75 M of at least one oxidizer capable of oxidizing silicon; and
0.15 to 2.2 M of soluble silicon.

12. The method of claim 11 wherein the as-prepared etching composition comprises:
2.5 to 7.1 M of hydrofluoric acid;
1 to 7.75 M of at least one oxidizer capable of oxidizing silicon; and
0.3 to 1.9 M of soluble silicon.

13. The method of claim 12 wherein the as-prepared etching composition comprises:
2.5 to 5.8 M of hydrofluoric acid;
3.8 to 7.75 M of at least one oxidizer capable of oxidizing silicon; and
0.6 to 1.7 M of soluble silicon.

14. The method of claim 7, wherein the one or more acid diluents are present in a concentration from 1.1 to 7.5 M.

15. The method of claim 14, wherein the one or more acid diluents are present in a concentration from 1.3 to 5.4 M.

16. The method of claim 15, wherein the one or more acid diluents are present in a concentration from 1.7 to 4.6 M.

17. The method of claim 1, wherein the resulting patterned silicon substrate has lower average reflectance than the same silicon substrate etched with the as-prepared etching composition wherein water is substituted for the soluble silicon.

18. An as-prepared aqueous acid etching composition, comprising:
1.4 to 7.1 M of hydrofluoric acid;
0.01 to 7.75 M of at least one oxidizer capable of oxidizing silicon; and
0.15 to 2.2 M of soluble silicon.

19. The as-prepared aqueous acid etching composition of claim 18, comprising:
2.5 to 7.1 M of hydrofluoric acid;
1 to 7.75 M of at least one oxidizer capable of oxidizing silicon; and
0.3 to 1.9 M of soluble silicon.

20. The as-prepared aqueous acid etching composition of claim 19, comprising:
2.5 to 5.8 M of hydrofluoric acid;
3.8 to 7.75 M of at least one oxidizer capable of oxidizing silicon; and
0.6 to 1.7 M of soluble silicon.

21. The as-prepared aqueous acid etching composition of claim 18, wherein the soluble silicon is selected from a group consisting of fluorosilicates, silicic acid, silicates and soluble silicon.

22. The as-prepared aqueous acid etching composition of claim 21 wherein the fluorosilicate is selected from a group consisting of hexafluorosilicic acid and ammonium fluorosilicate.

23. The as-prepared aqueous acid etching composition of claim 18, further comprising one or more acid diluents.

24. The as-prepared aqueous acid etching composition of claim 23, wherein the one or more acid diluents are present at a concentration of 1.1 to 7.5 M.

25. The as-prepared aqueous acid etching composition of claim 24, wherein the one or more acid diluents are present at a concentration of 1.3 to 5.4 M.

26. The as-prepared aqueous acid etching composition of claim 25, wherein the one or more acid diluents are present at a concentration of 1.7 to 4.6 M.

27. The as-prepared aqueous acid etching composition of claim 23, wherein the acid diluents are selected from the group consisting of acetic, glacial acetic, phosphoric, sulfuric, sulfurous, pyrophosphoric, phosphorus, chromic, chloric, trifluoromethanesulfonic, methanesulfonic, trifluoroacetic, trichloroacetic, formic, and citric acids; poly(4-styrenesulfonic acid), poly(vinylsulfonic acid), poly(styrene-alt-maleic acid), poly(acrylic acid), poly(methacrylic acid) and combinations thereof.

28. The as-prepared aqueous acid etching composition of claim 18, wherein the oxidizer is selected from the group consisting of nitric acid, nitrous acid, iodic acid, peroxides, chlorates, perchlorates, chromates, dichromates, nitrites, nitrates, permanganates, persulfates, iodates, periodates and combinations thereof.

29. A method of etching a silicon surface, comprising:
providing an as-prepared aqueous acid etching composition comprising 1.4 to 7.1 M aqueous hydrofluoric acid, 0.01 to 7.75 M of at least one aqueous oxidizer capable of oxidizing silicon, and 0.15 to 2.2 M aqueous hexafluorosilicic acid; and
exposing a silicon substrate to the as-prepared etching composition.
